(19) United States
(12) Patent Application Publication
(10) Pub. No.: US 2024/0411228 A1
(43) Pub. Date: Dec. 12, 2024

(54) PRODUCTION METHOD FOR SEMICONDUCTOR SUBSTRATES

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/699,377

(22) PCT Filed: Sep. 21, 2022
(86) PCT No.: PCT/JP2022/035101

§ 371 Date: Apr. 8, 2024

(30) Foreign Application Priority Data
Nov. 16, 2021 (JP) 2021-186131

(51) Int. Cl. G03F 7/16; C23C 16/18; C23C 16/30; C23C 16/455; C23C 16/50; C23C 16/56; G03F 7/20; H01L 21/033

(52) U.S. Cl. CPC G03F 7/167; C23C 16/18; C23C 16/30; C23C 16/45525; C23C 16/50; C23C 16/56; G03F 7/2004; H01L 21/0332

(57) ABSTRACT

A production method for a semiconductor substrate includes: performing a vapor deposition of a metal compound or metal directly or indirectly onto a substrate to form a metal-containing resist film; and exposing the metal-containing resist film to light. The metal compound or metal includes an Au atom, a Cr atom, an Ag atom, an In atom, or a combination thereof. The method preferably further includes developing the metal-containing resist film after exposing. The vapor deposition is preferably performed by PVD or CVD. The metal compound preferably includes a metal complex, a metal halide, or an organometal.

### TECHNICAL FIELD

The present invention relates to a production method for a semiconductor substrate.

### BACKGROUND ART

In a general method for forming a pattern to be used for microfabrication by lithography, a resist film formed from a radiation-sensitive composition for forming a resist film is exposed to an electromagnetic wave such as an ultraviolet ray, a far ultraviolet ray (e.g., an ArF excimer laser beam or a KrF excimer laser beam) or an extreme ultraviolet ray (EUV), or a charged corpuscular ray such as an electron beam to generate an acid in an exposed area. Then, a chemical reaction using this acid as a catalyst causes a difference in dissolution rate with respect to the developer between the exposed area and the unexposed area, and a pattern is thereby formed on a substrate. The pattern formed can be used as a mask or the like in substrate processing. The method for forming a pattern is required to improve resist performance along with miniaturization of processing technology. In response to this requirement, the types, molecular structures, and so on of an organic polymer, an acid generator, and other components to be used in a radiation-sensitive composition for resist film formation have been studied, and combinations thereof have also been studied in detail (see, for example, Patent Document 1). It has also been studied to use a metal-containing compound instead of the organic polymer.

### PRIOR ART DOCUMENT

### Patent Document

Patent Document 1: JP-A-2000-298347

### SUMMARY OF THE INVENTION

### Problems to be Solved by the Invention

In a resist pattern formed using the metal-containing compound described above, there may be a case where the resist pattern collapses or trailing of the pattern at the bottom of a resist film occurs.

In order to solve the above problems, an object of the present invention is to provide a production method for a semiconductor substrate capable of exhibiting sensitivity, LWR performance, and so on at a sufficient level.

### Means for Solving the Problems

The present invention relates to, in one embodiment, a production method for a semiconductor substrate, the method including:
a step of vapor depositing a metal compound or metal directly or indirectly onto a substrate to form a metal-containing resist film; and
a step of exposing the resist film to light,
wherein the metal compound or metal includes an Au atom, a Cr atom, an Ag atom, an In atom, or any of these atoms.

### Effect of the Invention

In accordance with the production method for a semiconductor substrate, a semiconductor substrate having a good pattern shape can be produced efficiently because of employing the step of vapor depositing a specific metal compound or metal to form a metal-containing resist film.

Therefore, the production method for a semiconductor substrate can suitably be used for, for example, producing semiconductor devices expected to be further microfabricated in the future.

### MODE FOR CARRYING OUT THE INVENTION

Hereinafter, production methods for a semiconductor substrate of respective embodiments of the present invention will be described in detail.

### <<Production Method for a Semiconductor Substrate>>

The production method for a semiconductor substrate includes a step of vapor depositing a metal compound or metal directly or indirectly onto a substrate to form a metal-containing resist film (hereinafter, also referred to as “metal-containing resist film formation step”) and a step of exposing the metal-containing resist film formed in the metal-containing resist film formation step to light (hereinafter, also referred to as “exposure step”). In addition, after the exposure step, a step of preparing a developer (hereinafter, also referred to as “developer preparation step”) or a step of dissolving an exposed area of the exposed metal-containing resist film with the developer to form a resist pattern (hereinafter, also referred to as “resist pattern formation step”) may be included. The method may further include a step of applying a composition for resist underlayer film formation directly or indirectly to the substrate (hereinafter, also referred to as “composition-for-resist-underlayer-film-formation application step”).

Hereinafter, each step of the production method for a semiconductor substrate will be described.

### [Composition-for-Resist-Underlayer-Film-Formation Application Step]

When a resist underlayer film is formed directly or indirectly on a substrate, the method may also include a composition-for-resist-underlayer-film-formation application step prior to the metal-containing resist film formation step. In this step, a composition for resist underlayer film formation is applied directly or indirectly to a substrate. As the composition for resist underlayer film formation, a known composition can be appropriately used. The method of the application of the composition for resist underlayer film formation is not particularly limited, and the application can be performed by an appropriate method such as spin coating, cast coating, or roll coating. As a result, a coating film is formed, and volatilization of the solvent in the composition for resist underlayer film formation occurs, so that a resist underlayer film is formed. The composition for resist underlayer film formation will be described later.

Next, the coating film formed by the application is heated. The formation of the resist underlayer film is promoted by the heating of the coating film. More specifically, volatilization or the like of the solvent in the composition for resist underlayer film formation is promoted by the heating of the coating film.

The heating of the coating film may be performed either in the air atmosphere or in a nitrogen atmosphere. The lower limit of the heating temperature is preferably 100° C., more preferably 150° C., and still more preferably 200° C. The upper limit of the heating temperature is preferably 400° C., more preferably 350° C., and still more preferably 280° C. The lower limit of the heating time is preferably 15 seconds, and more preferably 30 seconds. The upper limit of the time is preferably 1,200 seconds, and more preferably 600 seconds.

The lower limit of the average thickness of the resist underlayer film to be formed is preferably 0.5 nm, more preferably 1 nm, and still more preferably 2 nm. The upper limit of the average thickness is preferably 50 nm, more preferably 20 nm, still more preferably 10 nm, and particularly preferably 7 nm. The average thickness is measured as described in Examples.

### [Metal-Containing Resist Film Formation Step]

In this step, a metal-containing resist film is formed on the resist underlayer film formed optionally by the composition-for-resist-underlayer-film-formation application step.

The metal-containing resist film can be formed by depositing a metal compound on the resist underlayer film to be optionally formed.

The deposition of the metal compound may be performed by physical vapor deposition (PVD) or chemical vapor deposition (CVD). Among them, CVD is preferable, and may be performed by plasma enhanced (PE) CVD.

Deposition by CVD may be performed by atomic layer deposition (ALD). The deposition temperature by ALD may be 50° C. to 600° C. The deposition pressure by ALD may be 100 to 6000 mTorr. The flow rate of the metal compound by ALD may be 0.01 to 10 ccm and the gas flow rate (CO₂, CO, Ar, N₂) may be 100 to 10000 sccm. Plasma power by ALD may be 200 to 1000 W per 300 mm wafer station using radio-frequency plasma (e.g., 13.56 MHZ, 27.1 MHz, or a frequency higher than 27.1 MHZ).

Processing conditions suitable for vapor deposition by CVD include a deposition temperature of about 250° C. to 350° C. (for example, 350° C.), a reactor pressure of less than 6 Torr (for example, maintained at 1.5 to 2.5 Torr at 350° C.), a plasma power/bias of 200 W per 300 mm wafer station with a radio-frequency plasma (for example, 13.56 MHz or more), a metal compound flow rate of about 100 to 500 ccm, and a CO₂ flow rate of about 1000 to 2000 sccm.

The metal-containing resist film contains an Au atom, a Cr atom, an Ag atom, an In atom, or any of these atoms. In other words, the metal-containing resist film of the present invention contains at least one atom selected from the group consisting of an Au atom, a Cr atom, an Ag atom, and an In atom. Such a metal-containing resist film can be formed using a metal compound or a metal simple substance containing an Au atom, a Cr atom, an Ag atom, an In atom, or any of these atoms.

Examples of the metal compound include a metal complex, a metal halide, and an organometal.

Examples of the metal complex include a gold complex, a chromium complex, a silver complex, or an indium complex.

Examples of the metal halide include an indium halide.

Examples of the organometal include an alkylindium.

Examples of a metal compound containing an Au atom include gold complexes such as chloro(triphenylphosphine) gold (I). Gold as a sputtering target can also be used.

Examples of a metal compound containing a Cr atom include chromium complexes such as chromium (III) acetylacetonate, chromium (III) acetate hydroxide, chromium (III) tri(2,2,6,6-tetramethyl-3,5-heptadionate), hexacarbonylchromium, and bis(pentamethylcyclopentadienyl) chromium (III). Chromium as a sputtering target can also be used.

Examples of a metal compound containing an Ag atom include silver complexes such as silver acetate, silver trifluoroacetate, silver acetylacetonate, and (1,5-cyclooctadiene)(hexafluoroacetylacetonate) silver (I). Silver as a sputtering target can also be used.

Examples of a metal compound containing an In atom include indium halides such as indium chloride (III), indium complexes such as indium (III) acetylacetonate, and organoindiums such as indium (III) acetate, indium (III) acetate hydrate, and trimethylindium. Among the organoindiums, an alkylindium such as trimethylindium is preferable. Indium, ITO (a mixture of indium oxide and tin oxide), or IGZO (a mixture of indium oxide, gallium oxide, and zinc oxide) as a sputtering target can also be used.

The metal-containing resist film of the present invention may contain a metal atom other than an Au atom, a Cr atom, an Ag atom, or an In atom. Examples of such other metal atoms include an Sn atom, a Ge atom, a Pb atom, and an Hf atom, and an Sn atom is preferable.

### [Exposure Step]

In this step, the metal-containing resist film formed by the metal-containing resist film formation step is exposed to light. This step causes a difference in solubility in the developer between the exposed area and the unexposed area in the metal-containing resist film, or causes a difference in removal amount by development by heating between the exposed area and the unexposed area.

The radiation to be used for the exposure can be appropriately selected according to the type of the metal-containing resist film to be used, and so on. Examples of the radiation include electromagnetic waves such as visible rays, ultraviolet rays, far ultraviolet rays, X-rays, and Y-rays and corpuscular rays such as electron beams, molecular beams, and ion beams. Among these, far ultraviolet rays are preferable, and a KrF excimer laser beam (wavelength: 248 nm), an ArF excimer laser beam (wavelength: 193 nm), an F₂ excimer laser beam (wavelength: 157 nm), a Kr₂ excimer laser beam (wavelength: 147 nm), an ArKr excimer laser beam (wavelength: 134 nm) or extreme ultraviolet rays (wavelength: 13.5 nm, etc., also referred to as “EUV”) are more preferred, and EUV is still more preferred. In addition, exposure conditions can be appropriately determined according to the type of the metal-containing resist film to be used, and so on.

The EUV exposure causes a chemical reaction of a metal compound such as a dimerization reaction or a decomposition reaction in the exposed area of the metal-containing resist film. For example, in the case of indium (III) chloride, which is an indium halide compound, a decomposition reaction such as 2InCl₃→2 In+3Cl₂ can occur in the exposed area.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type of the material for forming the metal-containing resist film to be used, and so on. The lower limit of the PEB temperature is preferably 50° C., and more preferably 70° C. The upper limit of the PEB temperature is preferably 500° C., and more preferably 300° C. The lower limit of the PEB time is preferably 10 seconds, and more preferably 30 seconds. The upper limit of the PEB time is preferably 600 seconds, and more preferably 300 seconds.

### [Developer Preparation Step]

In this step, a developer is prepared. Examples of the developer include water, alcohol-based liquids, and ether-based liquids, and two or more kinds thereof may be used in combination.

Examples of the alcohol-based liquid include:
monoalcohol-based liquids such as methanol, ethanol, n-propanol, iso-propanol, n-butanol, iso-butanol, sec-butanol, t-butanol, n-pentanol, iso-pentanol, sec-pentanol, t-pentanol, 2-methylpentanol, and 4-methyl-2-pentanol.

Examples of the ether-based liquid include:
polyhydric alcohol partial ether-based solvents such as ethylene glycol monomethyl ether, ethylene glycol monoethyl ether, ethylene glycol dimethyl ether, and propylene glycol monoethyl ether, and polyhydric alcohol partial ether acetate-based liquids such as ethylene glycol monomethyl ether acetate, ethylene glycol monoethyl ether acetate, propylene glycol monomethyl ether acetate (PGMEA), and propylene glycol monoethyl ether acetate.

As the developer, water and alcohol-based liquids are preferable, and water, ethanol, or a combination thereof is more preferable.

### [Resist Pattern Formation Step]

In this step, the exposed metal-containing resist film is developed to form a resist pattern. For example, in the case of indium (III) chloride, which is an indium halide compound, it is difficult to remove a simple substance of indium, which can be generated in an exposed area, with a developer or by heating, whereas it is possible to remove indium (III) chloride in an unexposed area with a developer or by heating. Therefore, a resist pattern can be formed by development with a developer or by heating.

The temperature of the developer can be appropriately determined according to the type of the material for forming the metal-containing resist film to be used, and so on. The lower limit of the temperature of the developer is preferably 20° C., and more preferably 30° C. The upper limit of the temperature of the developer is preferably 70° C., and more preferably 60° C. The lower limit of the developing time is preferably 10 seconds, and more preferably 30 seconds. The upper limit of the developing time is preferably 600 seconds, and more preferably 300 seconds.

The temperature in the case of development by heating can be appropriately determined according to the type of the material for forming the metal-containing resist film to be used, and so on. The heating temperature may be 50° C. to 600° C.

In this step, washing and/or drying may be performed after the development.

### [Etching Step]

In this step, etching is performed using the resist pattern as a mask. The number of times of the etching may be once. Alternatively, etching may be performed a plurality of times, that is, etching may be sequentially performed using a pattern obtained by etching as a mask. Examples of an etching method include dry etching and wet etching. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the silicon-containing film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃, and inert gases such as He, N₂ and Ar are used. These gases can also be used in admixture.

### EXAMPLES

Hereinafter, the present invention will be specifically described with reference to Examples, but the present invention is not limited to these Examples. Methods for measuring various physical property values are shown below.

### <Preparation of Substrate for Evaluation>

### Example 1

A raw material for plasma CVD was prepared by mixing 2,4,6,8-tetramethylcyclotetrasiloxane and chloro(triphenylphosphine) gold (I) such that the gold concentration was 3 μg/L. Next, a substrate having a silicon dioxide film with a thickness of 20 nm formed on the surface thereof was set in a plasma CVD apparatus and evacuated. Thereafter, a metal-containing resist film containing Au atoms with a thickness of 5 nm was prepared on one side of the substrate using the above-described raw material for plasma CVD.

The metal-containing resist film was irradiated with extreme ultraviolet rays using an EUV scanner (“TWINSCAN NXE: 3300B”, available from ASML Co. (NA=0.3; Sigma=0.9; quadrupole illumination, with a 1:1 line and space mask having a line width of 16 nm in terms of a dimension on wafer)). Thereafter, the substrate was developed using 4-methyl-2-pentanol and then dried. In this way, a substrate for evaluation on which a resist pattern containing Au atoms was formed was prepared.

### Example 2

A substrate having a silicon dioxide film with a thickness of 20 nm formed on the surface thereof was set in a CVD apparatus and evacuated. Thereafter, using hexacarbonylchromium, a metal-containing resist film containing Cr atoms with a thickness of 7 nm was formed on one side of the substrate.

The metal-containing resist film was irradiated with extreme ultraviolet rays using the EUV scanner specified above. Thereafter, the substrate was developed using 4-methyl-2-pentanol and then dried. In this way, a substrate for evaluation on which a resist pattern containing Cr atoms was formed was prepared.

### Example 3

A substrate having a silicon dioxide film with a thickness of 20 nm formed on the surface thereof was set in an ALD apparatus and evacuated. Thereafter, a metal-containing resist film containing Ag atoms with a thickness of 3 nm was formed on one side of the substrate using a 0.1 M solution of (1,5-cyclooctadiene) (hexafluoroacetylacetonate) silver (I) in toluene.

The metal-containing resist film was irradiated with extreme ultraviolet rays using the EUV scanner specified above. Thereafter, development was performed by a paddle method for 60 seconds using n-propanol.

An etchant having phosphoric acid/nitric acid/acetic acid=45/2. 2/30 (wt %) was prepared by mixing 85 wt % phosphoric acid, 70 wt % nitric acid, 99 wt % acetic acid, and ultrapure water. The developed substrate was immersed for 60 seconds in the etchant adjusted to 30° C. In this way, a substrate for evaluation on which a resist pattern containing Ag atoms was formed was obtained.

### Example 4

A substrate having a silicon dioxide film with a thickness of 20 nm formed on the surface thereof was set in a CVD apparatus and evacuated. Thereafter, using trimethylindium, a metal-containing resist film containing In atoms with a thickness of 5 nm was formed on one side of the substrate.

The metal-containing resist film was irradiated with extreme ultraviolet rays using the EUV scanner specified above. Thereafter, the substrate was developed by heating at 150° C. for 2 minutes. In this way, a substrate for evaluation on which a resist pattern containing In atoms was formed was obtained.

### Example 5

The same operation as in Example 4 was performed except that in Example 4 indium (III) chloride was used in place of trimethylindium and development using ultrapure water was performed in place of the development by heating at 150° C. for 2 minutes. In this way, a substrate for evaluation on which a resist pattern containing In atoms was formed was obtained.

### Comparative Example 1

A substrate for evaluation with a resist pattern containing Sn atoms formed thereof was obtained in the same manner as in Example 4 except that tetramethyltin was used in place of trimethylindium in Example 4.

### Comparative Example 2

A substrate having a silicon dioxide film with a thickness of 20 nm formed on the surface thereof was set in a plasma CVD apparatus and evacuated. Thereafter, a metal-containing resist film containing Sn atoms with a thickness of 20 nm was formed on one side of the substrate by CVD with trimethyltin chloride and carbon dioxide.

The metal-containing resist film was irradiated with extreme ultraviolet rays using the EUV scanner specified above. Thereafter, the substrate was developed by heating for 60 seconds using ethanol at 60° C. In this way, a substrate for evaluation on which a resist pattern containing Sn atoms was formed was obtained.

### <Evaluation>

Pattern rectangularity was evaluated in accordance with the following method. The evaluation results are shown in Table 1.

### [LWR]

The pattern was measured at 50 points, then a 3 sigma value was determined from the distribution of the measured values, and the value determined was defined as LWR (nm). The smaller the value is, the better the LWR is. Taking the value of the LWR of Comparative Example 1 as a reference value, an LWR was evaluated as “A” when the LWR was 95% or less of the reference value, evaluated as “B” when the LWR was more than 95% and less than 99% of the reference value, and evaluated as “C” when the LWR was more than 99% of the reference value. In the column of “LWR” in the following Table 1, “***” indicates the use as a reference for LWR evaluation.

TABLE 1

| | LWR |
|---|---|
| Example 1 | A |
| Example 2 | B |
| Example 3 | A |
| Example 4 | B |
| Example 5 | B |
| Comparative | *** |
| Example 1 | |
| Comparative | C |
| Example 2 | |

### Example 6

A raw material for plasma CVD was prepared by mixing 2,4,6,8-tetramethylcyclotetrasiloxane, chloro(triphenylphosphine) gold (I) and tris(dimethylamino)methyltin (IV) such that the concentrations of gold and tin were 1 μg/L and 4 μg/L, respectively.

A substrate for evaluation with a resist pattern containing Au atoms and Sn atoms with a thickness of 5 nm formed thereon was prepared in the same manner as in Example 1 except that the raw material described above was used. When evaluation was performed in the same manner as described above, the LWR was “A”.

As can be seen from Table 1 and the result of Example 6, the resist patterns formed from the metal-containing resist films containing an Au atom, a Cr atom, an Ag atom, an In atom, or any of these atoms were superior in LWR to the resist patterns formed from the metal-containing resist films free of these atoms.

### INDUSTRIAL APPLICABILITY

In accordance with the production method for a semiconductor substrate of the present invention, a resist pattern superior in LWR can be formed. Therefore, the production method for a semiconductor substrate can suitably be used for, for example, producing semiconductor devices expected to be further microfabricated in the future.

1. A production method for a semiconductor substrate, the method comprising:
performing a vapor deposition of a metal compound or metal directly or indirectly onto a substrate to form a metal-containing resist film; and
exposing the metal-containing resist film to light,
wherein the metal compound or metal comprises an Au atom, a Cr atom, an Ag atom, an In atom, or a combination thereof.

2. The method according to claim 1, further comprising developing the metal-containing resist film after exposing.

3. The method according to claim 1, wherein the vapor deposition is performed by PVD or CVD.

4. The method according to claim 1, wherein the metal compound comprises a metal complex, a metal halide, or an organometal.

5. The method according to claim 4, wherein the metal complex comprises a gold complex, a chromium complex, a silver complex, or an indium complex.

6. The method according to claim 4, wherein the metal halide comprises indium halide.

7. The method according to claim 4, wherein the organometal comprises an alkylindium.

8. The method according to claim 1, wherein exposing comprises exposing the metal-containing resist film to extreme ultraviolet rays.

9. The method according to claim 2, wherein the deposition is performed by PVD or CVD.

10. The method according to claim 9, wherein the metal compound comprises a metal complex, a metal halide, or an organometal.

11. The method according to claim 10, wherein the metal complex comprises a gold complex, a chromium complex, a silver complex, or an indium complex.

12. The method according to claim 10, wherein the metal halide comprises indium halide.

13. The method according to claim 10, wherein the organometal comprises an alkylindium.

14. The method according to claim 11, wherein exposing comprises exposing the metal-containing resist film to extreme ultraviolet rays.

15. The method according to claim 12, wherein exposing comprises exposing the metal-containing resist film to extreme ultraviolet rays.

16. The method according to claim 13, wherein exposing comprises exposing the metal-containing resist film to extreme ultraviolet rays.
